(19) United States
(12) Patent Application Publication
(10) Pub. No.: US 2007/0013462 A1
(43) Pub. Date: Jan. 18, 2007

(54) Dual-band bandpass filter

(75) Inventor: Fong-Sheng Fan, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/354,105

(22) Filed: Feb. 15, 2006

(30) Foreign Application Priority Data
Jul. 15, 2005 (TW) 094124125

(51) Int. Cl. H03H 7/01

(52) U.S. Cl. 333/185

(57) ABSTRACT

A dual-band bandpass filter for integrating two bandpass filters of two frequency bands includes a first filter unit and a second filter unit. The first filter unit is used to pass a signal of a first frequency band and the second filter unit is used to pass a signal of a second frequency band.

### BACKGROUND OF THE INVENTION

1. Field of Invention

The invention relates to a bandpass filter and, in particular, to a dual-band bandpass filter.

2. Related Art

Recently, due to the development in wireless technology, mobile phones and wireless local area network (WLAN) cards are widely spread. Among the radio-frequency passive devices in the mobile phones and WLAN cards, the filters are important components. Their primary function is to pass desired signals while filtering out irrelevant signals.

In general, both mobile phones and WLAN cards have dual-band modes. For example, a WLAN device can simultaneously operate in a first frequency band (with a central frequency of 2.4 GHz) and a second frequency band (with a central frequency of 5 GHz). Therefore, the WLAN device requires two bandpass filters operated at the same time for passing signals of the first frequency band and the second frequency band and filtering out irrelevant signals. This structure is against the objective of minimizing the volume and weight of the mobile phones and WAN cards. Therefore, it is an important subject of the invention to provide an effectively integrated dual-band bandpass filter.

### SUMMARY OF THE INVENTION

In view of the foregoing, the invention is to provide a dual-band bandpass filter that effectively integrates two filters.

To achieve the above, a dual-band bandpass filter of the invention includes a first filter unit and a second filter unit. In the invention, the first filter unit has a plurality of oscillators, and the second filter unit has a plurality of oscillators. Each oscillator in the first filter unit is electrically coupled to each oscillator in the second filter unit.

In addition, the invention also discloses a dual-band bandpass filter including an inductor stacked layer, a first capacitor stacked layer and a second capacitor stacked layer. In the invention, the inductor stacked layer has a plurality of inductors. The first capacitor stacked layer is disposed on one side of the inductor stacked layer and has a plurality of coupling capacitors and a plurality of ground capacitors. The ground capacitors of the first capacitor stacked layer are electrically coupled to the inductors. The second capacitor stacked layer is disposed on the other side of the inductor stacked layer and has a plurality of coupling capacitors and a plurality of ground capacitors. The ground capacitors of the second capacitor stacked layer are coupled to the inductors.

As mentioned above, the dual-band bandpass filter of the invention can effectively integrate two bandpass filters of two bands. The two bandpass filters of the dual-band bandpass filter pass a first frequency band signal and a second frequency band signal, respectively. A multi-layer structure is used to implement the dual-band bandpass filter of the invention to achieve the goals of minimizing its volume and weight.

### BRIEF DESCRIPTION OF THE DRAWINGS

The invention will become more fully understood from the detailed description given herein below illustration only, and thus is not limitative of the present invention, and wherein:

FIG. 1 is an equivalent circuit diagram of a dual-band bandpass filter according to a preferred embodiment of the invention;

FIG. 2 is a simulated response diagram of the dual-band bandpass filter according to the preferred embodiment of the invention;

FIG. 3 is a schematic diagram showing the structure of the dual-band bandpass filter according to the preferred embodiment of the invention;

FIG. 4 is a schematic diagram showing another structure of the dual-band bandpass filter according to the preferred embodiment of the invention; and

FIG. 5 a schematic diagram showing yet another structure of the dual-band bandpass filter according to the preferred embodiment of the invention.

### DETAILED DESCRIPTION OF THE INVENTION

The present invention will be apparent from the following detailed description, which proceeds with reference to the accompanying drawings, wherein the same references relate to the same elements.

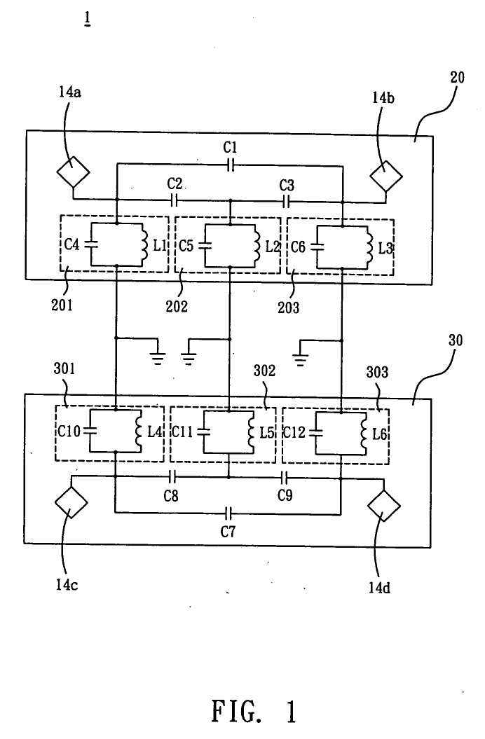

FIG. 1 shows an equivalent circuit diagram of a dual-band bandpass filter according to a preferred embodiment of the invention. As shown in FIG. 1, a dual-band bandpass filter 1 includes a first filter unit 20 and a second filter unit 30. In this embodiment, each of the first filter unit 20 and the second filter unit 30 is a three-order semi-lumped filter.

The first filter unit 20 has three oscillators 201 to 203, a first signal terminal 14a, and a second signal terminal 14b. The second filter unit 30 has three oscillators 301 to 303, a third signal terminal 14c, and a fourth signal terminal 14d. Each of the oscillators 201 to 203 is coupled to the corresponding one of the oscillators 301 to 303.

The oscillator 201 of the first filter unit 20 has a first ground capacitor C4 and a first inductor L1, both of which are coupled in parallel to form the oscillator 201. A first end of the oscillator 201 is grounded. The oscillator 202 has a second ground capacitor C5 and a second inductor L2. The oscillator 203 has a third ground capacitor C6 and a third inductor L3. The configurations of the oscillators 202 and 203 are the same as that of the oscillator 201, so the detailed descriptions of the oscillators 202 and 203 are omitted.

The oscillators 201 and 203 in this embodiment are electrically coupled via a first coupling capacitor C1. The oscillators 201 and 202 are electrically coupled via a second coupling capacitor C2. The oscillators 202 and 203 are electrically coupled via a third coupling capacitor C3. Besides, the first signal terminal 14a is electrically coupled to a second end of the oscillator 201. The second signal terminal 14b is electrically coupled to a second end of the oscillator 203.

The oscillator 301 of the second filter unit 30 in this embodiment has a fourth ground capacitor C10 and a fourth inductor L4, both of which are coupled in parallel to form the oscillator 301. A first end of the oscillator 301 is grounded. The oscillator 302 has a fifth ground capacitor C11 and a fifth inductor L5. The oscillator 303 has a sixth ground capacitor C12 and a sixth inductor L6. The configurations of the oscillators 302 and 303 are the same as that of the oscillator 301, so the detailed descriptions of the oscillators 302 and 303 are omitted.

In this embodiment, the oscillators 301 and 303 are electrically coupled via a fourth coupling capacitor C7. The oscillators 301 and 302 are electrically coupled via a fifth coupling capacitor C8. The oscillators 302 and 303 are electrically coupled via a sixth coupling capacitor C9.

Moreover, the third signal terminal 14c is electrically coupled to a second end of the oscillator 301. The fourth signal terminal 14d is electrically coupled to a second end of the oscillator 303.

As described above, the dual-band bandpass filter of the invention passes a signal of a first frequency band and a signal of a second frequency band. The first signal terminal 14a and the second signal terminal 14b pass the signal of the first frequency band. The third signal terminal 14c and the fourth signal terminal 14d pass the signal of the second frequency band. In this embodiment, the central frequency of the first frequency band is about 2.4 GHz, and the central frequency of the second frequency band is about 5 GHz. However, the invention is not limited to these conditions, and the first and second frequency bands can be defined by the user.

Each of the first signal terminal 14a, the second signal terminal 14b, the third signal terminal 14c, and the fourth signal terminal 14d of the dual-band bandpass filter 1 can be designed to have a resistance of 50Ω, so that the dual-band bandpass filter 1 can be directly used on a wireless device without further impedance matching.

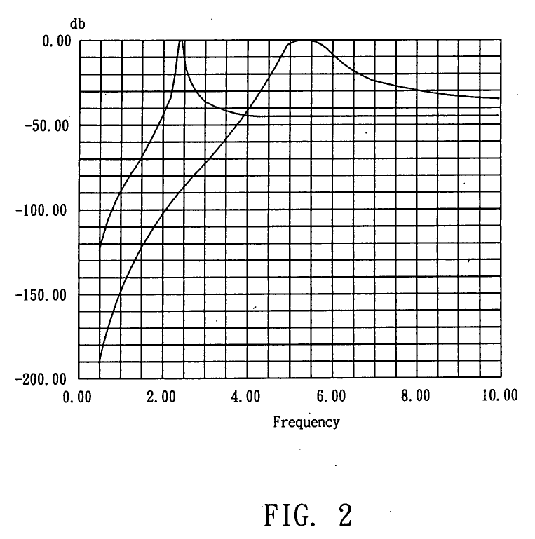

The simulated response curve shown in FIG. 2 illustrates the filtering characteristic of the dual-band bandpass filter 1. Since the dual-band bandpass filter 1 is a three-order semi-lumped filter and the oscillators 201 to 203 and the oscillators 301 to 303 are electrically coupled via the coupling capacitors, the dual-band bandpass filter 1 has desired characteristics.

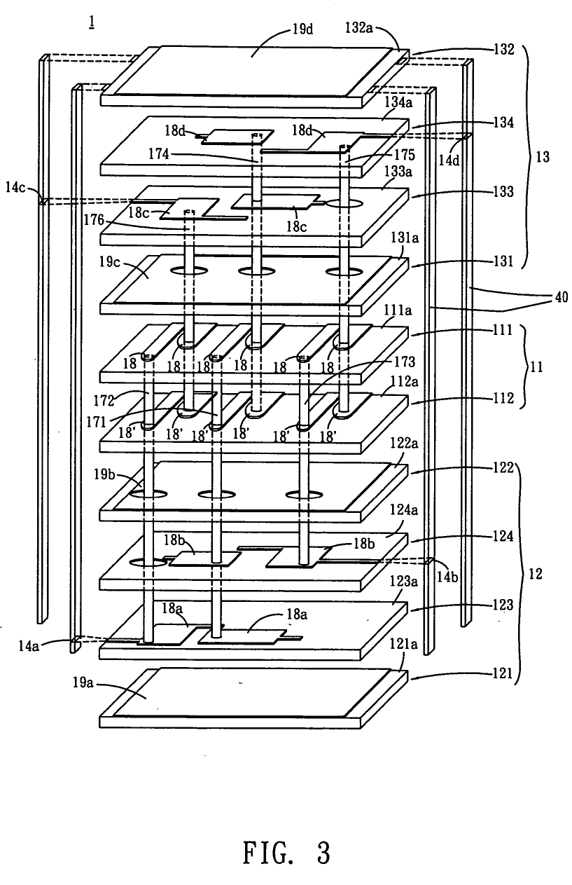

FIG. 3 is a schematic view of the structure of the dual-band bandpass filter according to the preferred embodiment of the invention. In other words, the invention uses the structure shown in FIG. 3 to implement the equivalent circuit diagram shown in FIG. 1.

In this preferred embodiment, the dual-band bandpass filter 1 includes an inductor stacked layer 11, a first capacitor stacked layer 12, a second capacitor stacked layer 13, a first signal terminal 14a, a second signal terminal 14b, a third signal terminal 14c, and a fourth signal terminal 14d.

The inductor stacked layer 11 includes a first inductor layer 111 and a second inductor layer 112. The first inductor layer 111 has a base 111a provided with several metal regions 18. The second inductor layer 112 has a base 112a disposed underneath the first inductor layer 111a. The base 112a is provided with several metal regions 18′.

Besides, the metal regions 18′ of the second inductor layer 112 and the metal regions 18 of the first inductor layer 111 are electrically coupled together, equivalent to the first inductor L1, the second inductor L2, the third inductor L3, the fourth inductor L4, the fifth inductor L5, and the sixth inductor L6 shown in FIG. 1.

In this embodiment, the first capacitor stacked layer 12 is disposed on one side of the first inductor stacked layer 11. The first capacitor stacked layer 12 includes a first ground layer 121, a second ground layer 122, a first capacitor layer 123, and a second capacitor layer 124. The first ground layer 121 has a base 121a provided with a first ground metal region 19a. The second ground layer 122 has a base 122a provided with a second ground metal region 19b.

The first capacitor layer 123 is disposed between the first ground layer 121 and the second ground layer 122. The first capacitor layer 123 has a base 123a provided with several metal regions 18a.

The second capacitor layer 124 is disposed between the first ground layer 121 and the second ground layer 122 and located on the first capacitor layer 123. The second capacitor layer 124 has a base 124a provided with several metal regions 18b.

The metal regions 18a of the first capacitor layer 123 and the first ground metal region 19a provide a capacitor effect, equivalent to the first ground capacitor C4 and the third ground capacitor C6 shown in FIG. 1. Moreover, one of the metal regions 18a of the first capacitor layer 123 and one of the metal regions 18b of the second capacitor layer 124 are electrically coupled via a first metal connecting portion 171 to provide a capacitor effect with the first ground metal region 19a that is equivalent to the second ground capacitor C5 shown in FIG. 1.

The metal regions 18a of the first capacitor layer 123 and the metal regions 18b of the second capacitor layer 124 provide several capacitor effects, equivalent to the first coupling capacitor C1, the second coupling capacitor C2, and the third coupling capacitor C3 shown in FIG. 1. Besides, the first ground capacitor C4 is electrically coupled to the first inductor L1 via a second metal connecting portion 172 to form the oscillator 201. The second ground capacitor C5 is electrically coupled to the second inductor L2 via the first metal connecting portion 171 to form the oscillator 202. The third ground capacitor C6 is electrically coupled to the third inductor L3 via a third metal connecting portion 173 to form the oscillator 203.

The second capacitor stacked layer 13 is disposed on the other side of the inductor stacked layer 11. The second capacitor stacked layer 13 includes a third ground layer 131, a fourth ground layer 132, a third capacitor layer 133, and a fourth capacitor layer 134. The third ground layer 131 has a base 131a provided with a third ground metal region 19c. The fourth ground layer 132 has a base 132a provided with a fourth ground metal region 19d.

The third capacitor layer 133 is disposed between the third ground layer 131 and the fourth ground layer 132. The third capacitor layer 133 has a base 133a provided with several metal regions 18c.

The fourth capacitor layer 134 is disposed between the third ground layer 131 and the fourth ground layer 132 and located on the third capacitor layer 133. The fourth capacitor layer 134 has a base 134a provided with several metal regions 18d.

The metal regions 18c of the third capacitor layer 133 and the fourth ground metal regions 19d provide a capacitor effect, equivalent to the fourth ground capacitor C10 and the sixth ground capacitor C12 shown in FIG. 1. One of the metal regions 18c of the third capacitor layer 133 and one of the metal regions 18d of the fourth capacitor layer 134 are electrically coupled via a fourth metal connecting portion 174 to provide a capacitor effect with the fourth ground metal region 19d that is equivalent to the fifth ground capacitor C11 shown in FIG. 1.

The metal regions 18c of the third capacitor layer 133 and the metal regions 18d of the fourth capacitor layer 134 provide several capacitor effects, equivalent to the fourth coupling capacitor C7, the fifth coupling capacitor C8, and the sixth coupling capacitor C9 shown in FIG. 1. Besides, the fourth ground capacitor C10 is electrically coupled to the fourth inductor L4 via a fifth metal connecting portion 175 to form the oscillator 301. The fifth ground capacitor C11 is electrically coupled to the fifth inductor L5 via a fourth metal connecting portion 174 to form the oscillator 302. The sixth ground capacitor C12 is electrically coupled to the sixth inductor L6 via a sixth metal connecting portion 176 to form the oscillator 303.

In this embodiment, the dual-band bandpass filter 1 further includes at least one electrode plate 40 for connecting the first ground metal region 19a, the second ground metal region 19b, the third ground metal region 19c, and the fourth ground metal region 19d. Moreover, the first signal terminal 14a is electrically coupled to the first capacitor layer 123. The second signal terminal 14b is electrically coupled to the second capacitor layer 124. The third signal terminal 14c is electrically coupled to the third capacitor layer 133. The fourth signal terminal 14d is electrically coupled to the fourth capacitor layer 134.

As described above, the dual-band bandpass filter is a multi-layer structure, which can be implemented by using the low-temperature co-fire ceramic technology. Thus, the equivalent circuit shown in FIG. 1 can be readily realized.

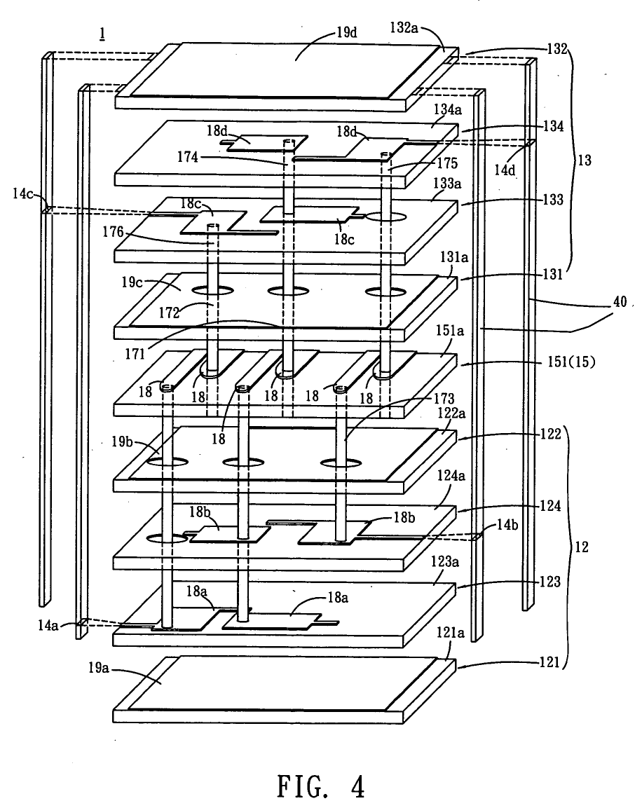

FIG. 4 is a schematic view showing another structure of the dual-band bandpass filter for implementing the equivalent circuit shown in FIG. 1. The dual-band bandpass filter 2 in the second embodiment of the invention has a first capacitor stacked layer 12, a second capacitor stacked layer 13, a first signal terminal 14a, a second signal terminal 14b, a third signal terminal 14c, and a fourth signal terminal 14d. The structures of the first capacitor stacked layer 12, second capacitor stacked layer 13, first signal terminal 14a, second signal terminal 14b, third signal terminal 14c, and fourth signal terminal 14d are the same as those shown in FIG. 3, so they are referred to the same references and are not described again. The difference between this embodiment and the first embodiment is that the inductor stacked layer 15 of this embodiment has only one first inductor layer 151. The first inductor layer 151 has a base 151a provided with several metal regions 18, equivalent to the fourth inductor L4, the fifth inductor L5, the sixth inductor L6, the third inductor L3, the second inductor L2, and the first inductor L1 shown in FIG. 1.

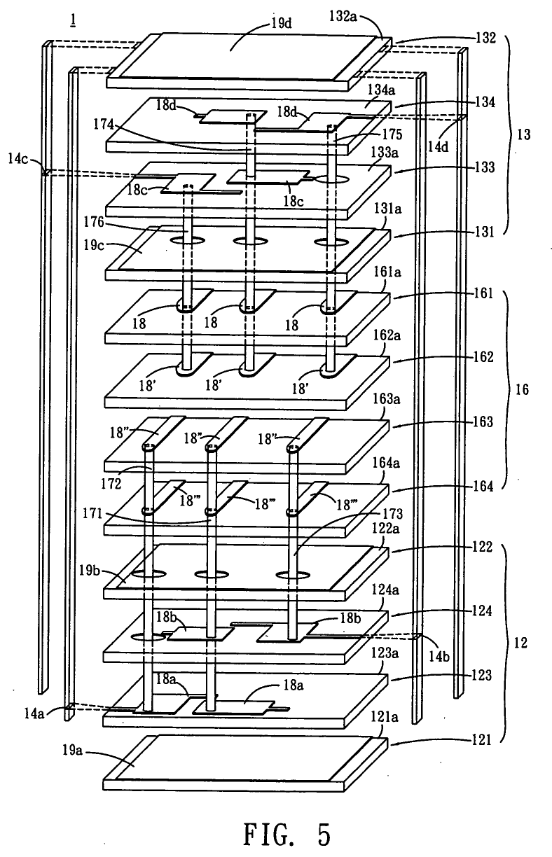

FIG. 5 is a schematic view showing yet another structure of the dual-band bandpass filter of the invention for implementing the equivalent circuit shown in FIG. 1. The dual-band bandpass filter 3 in the third embodiment has a first capacitor stacked layer 12, a second capacitor stacked layer 13, a first signal terminal 14a, a second signal terminal 14b, a third signal terminal 14c, and a fourth signal terminal 14d. The structures of these elements are the same as those shown in FIG. 3, so they are referred to the same references and are not described again. The difference between this embodiment and the second embodiment is that the inductor stacked layer 16 of this embodiment is different. The inductor stacked layer 16 in this embodiment has a first inductor layer 161, a second inductor layer 162, a third inductor layer 163, and a fourth inductor layer 164. The inductor layers 161, 162, 163, 164 mentioned above have bases 161a, 162a, 163a, 164a, respectively. The first inductor layer 161, the second inductor layer 162, the third inductor layer 163, and the fourth inductor layer 164 are respectively provided with several metal regions 18, 18′, 18″, and 18′″, equivalent to the first inductor L1, the second inductor L2, the third inductor L3, the fourth inductor L4, the fifth inductor L5, and the sixth inductor L6 shown in FIG. 1.

In summary, the dual-band bandpass filter of the invention can effectively integrate two bandpass filters of two frequency bands. The two bandpass filters of the dual-band bandpass filter pass a first frequency band signal and a second frequency band signal, respectively. A multi-layer structure is used to implement the dual-band bandpass filter of the invention to achieve the goals of minimizing its volume and weight.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A dual-band bandpass filter, comprising:
a first filter unit having a plurality of oscillators; and
a second filter unit having a plurality of oscillators, wherein each of the oscillators of the first filter unit is electrically coupled to corresponding one of the oscillators of the second filter unit.

2. The dual-band bandpass filter of claim 1, wherein the first filter unit and the second filter are three-order semi-lumped filters.

3. The dual-band bandpass filter of claim 1, wherein each of the oscillators has at least one capacitor and at least one inductor.

4. The dual-band bandpass filter of claim 3, wherein the capacitor and the inductor of the oscillator are connected in parallel and one end of the oscillator is grounded.

5. The dual-band bandpass filter of claim 1, wherein the first filter unit further has a first signal terminal electrically coupled to one of the oscillators of the first filter unit and a second signal terminal electrically coupled to another one of the oscillators of the first filter unit.

6. The dual-band bandpass filter of claim 5, wherein the second filter unit further has a third signal terminal electrically coupled to one of the oscillators of the second filter unit and a fourth signal terminal electrically coupled to another one of the oscillators of the second filter unit.

7. The dual-band bandpass filter of claim 1, wherein the oscillators are electrically coupled to each other via a coupling capacitor.

8. The dual-band bandpass filter of claim 1, wherein the first filter unit passes a signal of a first frequency band and the second filter unit passes a signal of a second frequency band.

9. The dual-band bandpass filter of claim 8, wherein the central frequency of the first frequency band is different from or smaller than the central frequency of the second frequency band.

10. A dual-band bandpass filter, comprising;
an inductor stacked layer having a first inductor layer;
a first capacitor stacked layer disposed on one side of the inductor stacked layer and having a plurality of capacitor layers and a plurality of ground layers, wherein one of the ground layers of the first capacitor stacked layer are electrically coupled to the first inductor layer; and
a second capacitor stacked layer disposed on the other side of the inductor stacked layer and having a plurality of capacitor layers and a plurality of ground layers, wherein one of the ground layers of the second capacitor stacked layer are coupled to the first inductor layer.

11. The dual-band bandpass filter of claim 10, further comprising a first signal terminal, a second signal terminal, a third signal terminal, and a fourth signal terminal, wherein the first signal terminal is electrically coupled to the first capacitor stacked layer, the second signal terminal is electrically coupled to the first capacitor stacked layer, the third signal terminal is electrically coupled to the second capacitor stacked layer, and the fourth signal terminal is electrically coupled to the second capacitor stacked layer.

12. The dual-band bandpass filter of claim 10, wherein the first inductor layer of the inductor stacked layer has a plurality of metal regions serving as inductors and electrically coupled to the first and second capacitor stacked layers via metal connecting portions.

13. The dual-band bandpass filter of claim 10, wherein the inductor stacked layer further comprises:
a second inductor layer disposed on the first inductor layer and having a plurality of metal regions electrically coupled to the first capacitor stacked layer via metal connecting portions, wherein the first inductor layer has a plurality of metal regions electrically coupled to the metal regions of the second inductor layer and the second capacitor stacked layer via metal connecting portions.

14. The dual-band bandpass filter of claim 10, wherein the first capacitor stacked layer comprises:
a first ground layer having a first metal region;
a second ground layer having a second metal region electrically coupled to the first metal region;
a first capacitor layer disposed between the first ground layer and the second ground layer and having a plurality of metal regions; and
a second capacitor layer disposed between the first ground layer and the second ground layer and having a plurality of metal regions.

15. The dual-band bandpass filter of claim 14, wherein one of the metal regions of the first capacitor layer and the first metal region form one ground capacitor of the first capacitor stacked layer, one of the metal regions of the second capacitor layer and the second metal region form another one ground capacitor of the first capacitor stacked layer, and another metal regions of the first capacitor layer and another metal regions of the second capacitor layer form coupling capacitors of the first capacitor stacked layer.

16. The dual-band bandpass filter of claim 10, wherein the second capacitor stacked layer comprises:
a third ground layer having a third metal region;
a fourth ground layer having a fourth metal region electrically coupled to the third metal region;
a third capacitor layer disposed between the third ground layer and the fourth ground layer and having a plurality of metal regions; and
a fourth capacitor layer disposed between the third ground layer and the fourth ground layer and having a plurality of metal regions.

17. The dual-band bandpass filter of claim 16, wherein one metal region of the third capacitor layer and the third metal region form one ground capacitor of the second capacitor stacked layer, one metal region of the fourth capacitor layer and the fourth metal region form another one ground capacitor of the second capacitor stacked layer, and another metal regions of the third capacitor layer and another metal regions of the fourth capacitor layer form coupling capacitors of the second capacitor stacked layer.

18. The dual-band bandpass filter of claim 10, wherein the dual-band bandpass filter is a low-temperature co-fire ceramic structure.

19. The dual-band bandpass filter of claim 10, further comprising at least one electrode plate electrically connected to the first capacitor stacked layer, the second capacitor stacked layer and the inductor stacked layer.

20. The dual-band bandpass filter of claim 10, wherein the inductor stacked layer further comprises a second inductor layer, a third inductor layer and a fourth inductor layer, wherein the first and second inductor layers respectively have metal regions electrically coupled to the second capacitor stacked layer via a plurality of metal connecting portions, and the third and fourth inductor layers respectively have metal regions electrically coupled to the first capacitor stacked layer via a plurality of metal connecting portions.
